(19) United States
(12) Patent Application Publication
(10) Pub. No.: US 2018/0133991 A1
(43) Pub. Date: May 17, 2018

(54) Metallized Plastic Pet Product

(71) Applicant: OurPet's Company, Fairport Harbor, OH (US)

(72) Inventor: Steven Tsengas, Fairport Harbor, OH (US)

(73) Assignee: OurPet's Company, Fairport Harbor, OH (US)

(21) Appl. No.: 15/646,148

(22) Filed: Jul. 11, 2017

Related U.S. Application Data
(60) Provisional application No. 62/337,690, filed on May 17, 2016.

(51) Int. Cl. B29D 22/00; A01K 5/01; A01K 7/00; A01K 1/01; B29C 45/00; B29C 49/42; B29C 43/02; B29C 51/26; C23C 14/20; C25D 3/00

(52) U.S. Cl. CPC B29D 22/003; A01K 5/0114; A01K 7/00; A01K 1/0107; C25D 3/00; B29C 49/42; B29C 43/02; B29C 51/261; C23C 14/205; B29C 45/0053

(57) ABSTRACT

A variety of pet related products are provided formed initially of plastic and finalized with a metallized surface finish. The pet product is molded using injection molding, rotational molding, vacuum forming, blow molding, compression molding, thermoforming or other plastic forming techniques that can provide a structure having a shape that cannot be readily or economically shaped by metal stamping or other conventional metalworking method. The semi finished plastic part is then subjected to a metallizing process in an individualized non-contiguous manner, where a thin metallic layer is deposited on at least one of the product surfaces. The resultant pet product item simulates the appearance metal, and may provide the durability, cleanability and the general antimicrobial nature resulting metal surfaces.

### RELATED APPLICATIONS

There present invention claims benefit of U.S. Provisional Application 62/337,690 filed on May 17, 2016. There are no other previously filed, nor currently any co-pending applications, anywhere in the world.

### BACKGROUND OF THE INVENTION

### 1. Field of the Invention

The present invention relates to a system and method for the production of low cost, durable pet products having high perceived quality features and, more particularly, to the a process for providing various molded plastic pet products resulting therefrom having a metallic appearance.

### 2. Description of the Related Art

Many pet products are molded of plastic or rubber, while others are made of metal. Many interactive toys for cats or dogs that are designed for play, mastication or other interaction are made of molded plastic or rubber. Generally, cost, durability and safety are key factors in the design of such products and in the final engineering selection of materials of construction. When it comes to feeders or water bowl, metal structures exist due to durability, cleanability and the general antimicrobial nature resulting from stainless steel surfaces. However, such feeders and water bowl are also available formed of plastic, which provides a wider range of design options at competitive material and manufacturing costs. Many larger housing products (i.e. litter boxes, larger elevated dog feeders, housings for larger pet products) could benefit both functionally and aesthetically from an option of metallic construction; however, economic limitations that exist in the market simply prevent these options from being explored.

As such, currently a need exist for providing for processes and products therefrom that can utilize the breadth of design options that result from plastic, while still providing the appearance and some of the functionality of metal construction.

Some methods and devices are known that incorporate metal coated plastic formed bodies. For example:

U.S. Pat. No. 6,983,542, issued in the name of Mithal et al., discloses metallized cutlery and tableware in which plastic cutlery items are fabricated primarily from a plastic material, such as polystyrene, and then subsequently having a metallic coating that imparts to this cutlery item the appearance of metal cutlery or silverware. U.S. Pat. No. 8,176,641 is related and further claims the metal surface finish simulating genuine metal cutlery, and the metal coating being less than about 2000 nanometers thick.

U.S. Pat. No. 8,100,450, issued in the name of Mithal et al., discloses food service tongs and a mold and method for making them. The tongs are again molded of plastic, and coated with a thin metallic layer to impart a metal-like appearance to these articles.

U.S. Pat. No. 8,316,803, issued in the name of Turner, discloses a pet door hood that is adapted to partially enclose the exterior and/or interior of a pet door or other animal access opening. The pet door hood may be formed to protect the pet door from weather, from entry by stray animals, and/or from entry or access by humans. In this disclosure, the wall members and/or portions thereof are anticipated of being formed of, inter alia, a “metallized, mirrored” material or other “decorative surface treatment”.

U.S. Patent Application Publication U.S.2007/0269142 describes a resealable bowl-in-pouch arrangement and method that anticipates the use of a “bowl-in-pouch” attachment with the use metallized polyester/polyolefin laminate film anticipated.

And, U.S. Patent Application Publication U.S.2008/0077214 describes a device and method for cooling animals in which a covering for animals is provided that anticipates the external layer of the device is comprised a fabric of woven plastic or synthetic stranded material with a metallic coating, for example, which provides high reflectivity for a broad bandwidth of radiation.

As can be seen by the dearth of any pet products that incorporate metallized finishes, the us of such technology is currently outside of the level of ordinary skill in the relevant art and further there is no apparent need for or inspiration derived from the use of metallized plastic cutlery or serving tongs as it pertains to the design, development and use of a variety of pet related products. Thus, it can be readily established that the application of the present invention would provide improved utility through pet related products in a manner unanticipated by existing art, individually or in combination, as related to the field of pet product development, manufacture and utilization, and otherwise is not obvious over a combination of references within the field of the invention and disclosures outside of the field of the invention.

It is thus an object of the present invention to provide a method making various pet products having unique shapes that cannot be readily shaped by metal stamping or other metalworking method.

It is another object of the present invention that such pet products be formed of plastic injection molding to take a desired shape that is subsequently metallized or electroplated to create an aesthetic, durable, hygienic shiny, metal finish.

It is yet another object of the present invention to provide a variety of pet products utilizing such a processes.

It is still another object of the present invention to provide such products that include bowls, waterers, food storage bins, larger elevated dog feeders, food scoops, litter scoops, housings for larger pet products or the like.

Further objects of the invention will become apparent in the course of the following description.

### SUMMARY OF THE INVENTION

The present invention provides a system and method making a variety of pet related products formed initially of plastic and finalized with a metallized surface finish. The pet product is preferably formed as a pet food or water bowl, but is not meant to be limited to such a form factor and may include food storage bins, elevated bid dog feeders, food scoops, litter scoops, litter boxes, housings for larger pet products and the like. In any embodiment variant the pet product is molded using injection molding, rotational molding, vacuum forming, blow molding, compression molding, thermoforming or other plastic forming techniques that can provide a structure having a shape that cannot be readily or economically shaped by metal stamping or other conventional metalworking method. The semi finished plastic part is then subjected to a metallizing process in an individualized non-contiguous manner, where a thin metallic layer is deposited on at least one of the product surfaces. Metallizing can occur through sputtering deposition, vapor deposition under vacuum, electroplating, auto catalytic or non-galvanic plating methods, or any hybrid, adapted or equivalent method. The metallic coating may optionally be enhanced by subjecting the metal surface to a post-metallizing holding period or by applying a clear protective overcoat. The resultant pet product item simulates the appearance metal, and may provide the durability, cleanability and the general antimicrobial nature resulting metal surfaces.

Further features and advantages of the invention will become apparent in the course of the following description.

### BRIEF DESCRIPTION OF THE DRAWINGS

The advantages and features of the present invention will become better understood with reference to the following more detailed description and claims taken in conjunction with the accompanying drawings, in which like elements are identified with like symbols, and in which:

FIG. 1 is a perspective view of an intake limiting pet food bowl according to the preferred embodiment of the present invention presented in a first configuration;

FIG. 2 is a top plan view thereof;

FIG. 3 is a bottom plan view thereof;

FIG. 4 is a perspective view of an intake limiting pet food bowl according to the preferred embodiment of the present invention presented in a second configuration;

FIG. 5 is a top plan view thereof;

FIG. 6 is a bottom plan view thereof; and

FIG. 7 is a partial cross sectional elevational view thereof.

### DESCRIPTION OF THE PREFERRED EMBODIMENTS

Before explaining the present invention in detail, it is important to understand that the invention is not limited in its application to the details of an intake limiting pet food bowl construction as illustrated, and the steps described herein may be broadly, equivalently adapted to the production of the wide variety of pet product constructions envisioned above. As such, the invention is capable of other embodiments and of being practiced or carried out in a variety of ways. It is to be understood that the phraseology and terminology employed herein is for the purpose of description of a preferred embodiment solely for the purposes of enabling an invention as understood at the time of filing and not of limitation.

In consideration of the above disclaimer, the best mode for carrying out the invention is presented in terms of its preferred embodiment, herein depicted within the Figures.

### 1. Detailed Description of the Figures

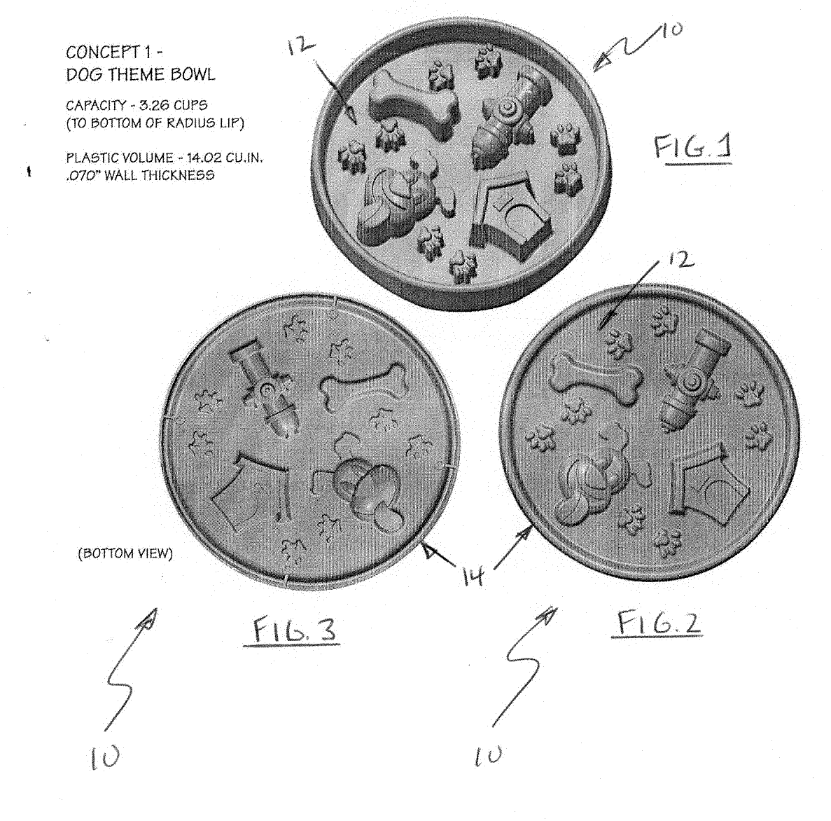

Referring now to the drawings, wherein like reference numerals indicate the same parts throughout the several views, a pet food or water bowl, generally noted at 10 is shown according to a preferred embodiment of the present invention. FIG. 1-3 show a slow feed pet feeder bowl 10 (hereinafter synonymously referred to as “bowl”, “pet bowl”, “feeder”, “pet feeder”, and “dish”) according to a first configuration of the preferred embodiment of the present invention. The bowl 10 forms a containment volume 12 formed within a circumferential outer lip or rim 14. Traditional feed limiting pet food bowls formed of metal are limited by the mechanical application of metal working techniques, and as such result in a generally annular-shaped trough around a single or a small number of blunt upward protuberances which forces a pet to progressively move in a circular fashion there around while it eats. Utilizing the present invention, a containment volume 12 is formed having a plurality of upwardly disposed interference structures 16 that form a tortuous path configuration there between, which will similarly force the pet to progressively moved throughout the trough 12 in order to access the contents. Such impediments result in slower eating habits being forced into the pet's behaviors.

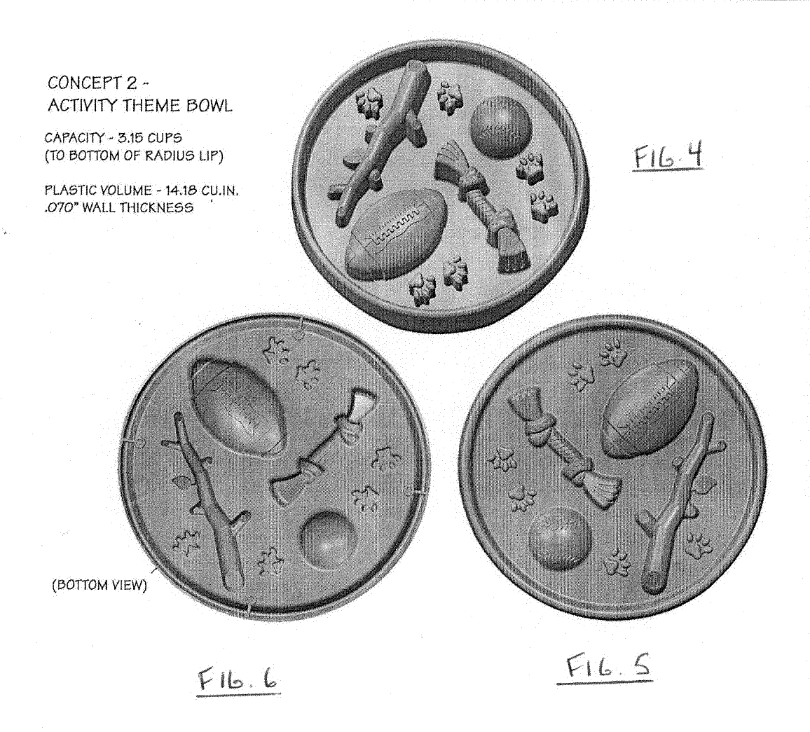

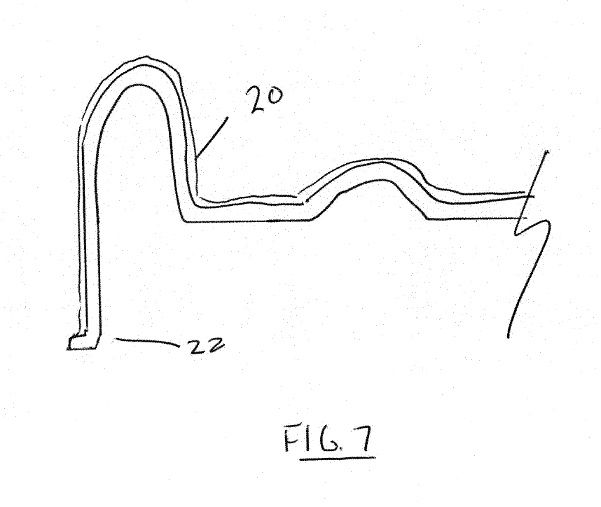

In the first configuration shown in FIG. 1-3, the interference structures 16 are formed in images having a first theme, herein shown as a dog theme with various imaged shaped structures 16. As shown in FIG. 4-6, the interference structures 18 are formed in images having a second theme, herein shown as an activity theme with various imaged shaped structures 18.

In either variant, the present invention provides the base structure of the pet related product, herein the bowl 10, formed initially of plastic. Numerous thermoplastic or thermoset resins may be utilized for forming an intricate pet product body structure in an economic and efficient manner while still imparting desired mechanical and processing functional characteristics. By way of example, and not meant as a limitation, these may include polystyrene (PS), polymethyl methacrylate (PMMA), acrylonitrile-butadiene-styrene (ABS), styrene-acrylonitrile (SAN) and polycarbonate (PC).

The selection of any particular resin would currently appear to be merely a design selection based upon product engineering and manufacturing effectiveness or optimization and having good physical properties and desirable flow, melt viscosity and molding characteristics from a production and manufacturing standpoint.

The bowl 10 may thereby be formed of a structurally sufficient plastic molded member having its general construction in accordance with the present invention. The pet product is preferably formed as a pet food or water bowl, but is not meant to be limited to such a form factor and may include food storage bins, elevated bid dog feeders, food scoops, litter scoops, litter boxes, housings for larger pet products and the like. In any embodiment variant the pet product is molded using injection molding, rotational molding, vacuum forming, blow molding, compression molding, thermoforming or other plastic forming techniques that can provide a structure having a shape that cannot be readily or economically shaped by metal stamping or other conventional metalworking method. A surface-coating layer 20 of metal is subsequently deposited on at least one of the surfaces of the pet product structure to impart the appearance, and at least partial functionality, of a metallic surface.

In the most preferred embodiment of the invention the metallic coating is applied to the side that is facing-up or otherwise functional as a feeder. The metallic coating 20 is very thin in relation to the bulk of the article (not shown to scale) and follows the contours on the surface of the part. The thickness of the metallic coating can vary depending upon the particular application, but for weight, cost and manufacturing time, a thin layer is preferred. Also, it should be readily apparent that depositing the metal layer on only one side of the article offers several economic advantages in comparison to coating the entire article. Firstly, there is a metallic material savings, as approximately only one-half of the surface area of the parts is metallized. Secondly, there is only one pass through the metallizer, and the parts are not subjected to the deposition mechanism twice to accommodate both sides. Thirdly, metallizing cycle-time is halved as it takes approximately half as long to deposit the metal on only one side of the parts. Finally, the process provides a simpler part handling, as the complex part handling mechanisms for turning/flipping the parts for metallizing both sides are avoided.

Metal coating on pet product article can be applied by any of the known vacuum deposition procedures. The semi finished plastic part is subjected to a metallizing process in an individualized non-contiguous manner, where a thin metallic layer is deposited on at least one of the product surfaces. Metallizing can occur through sputtering deposition, vapor deposition under vacuum, electroplating, auto catalytic or non-galvanic plating methods, or any hybrid, adapted or equivalent method. Vacuum metallization or deposition is the deposition of a film or coating in a vacuum or low-pressure plasma environment. The term plasma generally refers to an ion- or electron-rich gaseous environment for providing appreciable electrical conductivity. Vacuum deposition is a term that is applied to processes that deposit atoms or molecules one at a time, such as in physical vapor deposition (PVD) or low-pressure chemical vapor deposition (LPCVD).

The metallic coating may optionally be enhanced by subjecting the metal surface to a post-metallizing holding period or by applying a clear protective overcoat. The resultant pet product item simulates the appearance metal, and may provide the durability, cleanability and the general antimicrobial nature resulting metal surfaces.

In addition to the above features and benefits, a rubber bonded ring or rubber feet 22 may be provided to a lower surface of the outer edge of the bowl where the sidewall interfaces at a floor or supporting surface. In an alternate embodiment to the invention, the entire bottom portion of the bowl may comprise the rubber, non-skid surface.

In a preferred embodiment, the material chosen for the bonded ring or foot 22 is preferably a pliable material such as rubber, pastisol, or a polymer based material. In a preferred embodiment, the material is capable of providing resistance to the bowl 10 to substantially reduce slipping and/or sliding along the floor or other surface upon which it is placed.

### 2. Operation of the Preferred Embodiment

In operation, present invention provides a metallized plastic pet product, as well as a system and method for the production of low cost, durable pet products having high perceived quality features. Once a selected pet related product is formed initially of plastic, a metallized surface finish is applied to at least a part of at least one element of the plastic. In such a process, a structure having a shape that cannot be readily or economically shaped by metal stamping or other conventional metalworking method can be formed from injection or other molding and subsequently metallized. Products such as pet food bowls, water bowl, pet food storage bins, elevated feeders, a pet food scoops, litter scoops and even litter boxes may be provided for otherwise conventional use but including the objects, features and advantages of the present improvement.

The foregoing descriptions of specific embodiments of the present invention are presented for purposes of illustration and description. They are not intended to be exhaustive nor to limit the invention to precise forms disclosed and, obviously, many modifications and variations are possible in light of the above teaching. The embodiments are chosen and described in order to best explain principles of the invention and its practical application, to thereby enable others skilled in the art to best utilize the invention and its various embodiments with various modifications as are suited to the particular use contemplated. It is intended that a scope of the invention be defined broadly by the Drawings and Specification appended hereto and to their equivalents, and the scope of the invention is only to be limited only the following claims.

What is claimed is:

1. A process for making molded plastic pet products having a metallic plated surface comprising:
forming an initial pet product component of plastic; and
applying a metallized surface finish to at least a part of at least one element of said plastic;
wherein said pet product component provides a structure having a shape that cannot be readily or economically shaped by metal stamping or other conventional metalworking method.

2. The process of claim 1, wherein said initial product component of plastic is selected from the group comprising: a pet food bowl; a pet water bowl; a pet food storage bin; an elevated bid dog feeders; a pet food scoop; a litter scoop; a litter box; and a housing for larger pet products.

3. The process of claim 1, wherein forming an initial pet product component of plastic is accomplished through molded using injection molding, rotational molding, vacuum forming, blow molding, compression molding, thermoforming or other plastic forming techniques.

4. The process of claim 1, wherein applying a metallized surface finish to at least a part of at least one element of said plastic is provided an individualized non-contiguous manner, where a thin metallic layer is deposited on at least one of the product surfaces.

5. The process of claim 4, wherein metallizing is accomplished from a process selected from the group comprising: sputtering deposition; vapor deposition under vacuum; electroplating; auto catalytic or non-galvanic plating methods; or any hybrid, adapted or equivalent method.

6. The process of claim 5, wherein said metallic coating if further enhanced by subjecting the metal surface to a post-metallizing holding period or by applying a clear protective overcoat.
